(19) United States
(12) Patent Application Publication
(10) Pub. No.: US 2025/0118526 A1
(43) Pub. Date: Apr. 10, 2025

(54) PARTICLE BEAM SYSTEM WITH COOLING SYSTEM

(71) Applicant: Carl Zeiss Microscopy GmbH, Jena (DE)

(72) Inventor: Andreas Schmaunz, Oberkochen (DE)

(21) Appl. No.: 18/910,600

(22) Filed: Oct. 9, 2024

(30) Foreign Application Priority Data
Oct. 10, 2023 (DE) 10 2023 127 651.4

(51) Int. Cl. H01J 37/20; H01J 37/16

(52) U.S. Cl. CPC H01J 37/20; H01J 37/16; H01J 2237/2001

(57) ABSTRACT

A particle beam system comprises: an object mount for mounting an object to be examined; a particle beam source; a lens for focusing the particle beam; a detector; and a cooling system for cooling the object mount. The cooling system comprises: a coolant passage through the object mount; a supply port; an outlet; a heat exchanger having two passages; a first connecting line connected to the inlet of the coolant passage and the first passage through the heat exchanger; a second connecting line connected to the outlet of the coolant passage and the second passage through the heat exchanger; a third connecting line connected to the first passage through the heat exchanger and the supply port; a fourth connecting line connected to the second passage through the heat exchanger and the outlet; and a cooling mechanism for cooling a portion of the first connecting line.

### Cross-Reference to Related Application

This application claims benefit under 35 U.S.C. § 119 to German Application No. 10 2023 127 651.4, filed Oct. 10, 2023. The entire disclosure of this application is incorporated by reference herein.

### FIELD

The present disclosure relates to a particle beam system having a cooling system and to a method of operating such a particle beam system.

### BACKGROUND

In some cases, the examination of microscopic structures of an object comprises recording particle-optical images by virtue of using a particle beam system that scans a region on the object using a particle beam. There is a desire to keep a temperature of the object low for the purpose of recording the particle-optical image, especially in the case of biological and chemical objects. In this regard, use is usually made of an object mount for mounting the object in the particle beam system, the object mount being connected to a nitrogen cooling mechanism. For example, an object mount of this type is available under the product name “PP3006 CoolLok” or “PP3005 SEMCool” from Quorum Technologies Ltd, Laughton, United Kingdom.

Conventionally, such nitrogen cooling mechanisms use gaseous nitrogen as a coolant and liquid nitrogen for cooling the gaseous nitrogen. The liquid nitrogen evaporates during the operation of the nitrogen cooling mechanism for cooling the object mounted on the object mount. Accordingly, the user of the particle beam system with this nitrogen cooling mechanism regularly refills liquid nitrogen into the cooling system; this is linked to increased costs and more outlay for the user.

### SUMMARY

The present disclosure seeks to reduce liquid nitrogen consumption.

A particle beam system is proposed, comprising an object mount for mounting an object to be examined, a particle beam source for creating a particle beam, a lens for focusing the particle beam on the object, a detector for detecting signals created at the object by the particle beam and a cooling system for cooling the object mount, wherein the cooling system comprises a coolant passage through the object mount, having an inlet port and an outlet port; a supply port for feeding a gas; an outlet for removing the gas; a heat exchanger having a first passage and a second passage, the first passage and the second passage each comprising an inlet opening and an outlet opening; a first connecting line, the first end of which is connected to the inlet port of the coolant passage through the object mount, and the second end of which is connected to the outlet opening of the first passage through the heat exchanger; a second connecting line, the first end of which is connected to the outlet port of the coolant passage through the object mount, and the second end of which is connected to the inlet opening of the second passage through the heat exchanger; a third connecting line, wherein during cooling operation the first end of which is connected to the inlet opening of the first passage through the heat exchanger, and the second end of which is connected to the supply port; a fourth connecting line, wherein during cooling operation the first end of which is connected to the outlet opening of the second passage through the heat exchanger, and the second end of which is connected to the outlet; and a cooling mechanism for cooling at least a first portion of the first connecting line.

This means that the proposed particle beam system comprises a cooling system in which cold gas still flows through a heat exchanger after flowing through the coolant passage through the object mount, and hence after the object mount has been cooled, and the heat exchanger still allows the cold gas, before the latter is released into the surroundings, to absorb heat from gas that is newly fed and thus pre-cool the gas that is newly fed. As a result, a quantity of heat transferred to liquid nitrogen in the cooling mechanism from the gas that is newly fed is reduced, and so the liquid nitrogen consumption is reduced. Moreover, an energy consumption of the cooling system is reduced since the energy expended to cool the gas is used more effectively.

It should be observed that a connection by the connecting lines comprises the case in which further functional components might be arranged between the first end and the second end of the respective connecting line. For example, valves, sensors, regulators or the like might be arranged between the first end and the second end of the first connecting line, or between the inlet port of the coolant passage and the outlet port of the first passage through the heat exchanger.

According to some embodiments, the cooling system further comprises a reducing valve arranged in the flow of gas between the supply port and the outlet and providing a variable resistance to the flow of gas through the reducing valve; a temperature sensor for outputting a signal that represents a temperature of the object mount; and a controller configured to control the reducing valve on the basis of the signal that represents the temperature of the object mount. For example, the reducing valve is a turning valve, an electrically controllable valve or the like, by which a flow of gas can be set.

In this case, the reducing valve is a valve capable of setting an amount of gas flowing through the cooling system. The reducing valve can be an electrically controllable valve, for example a magnetic valve that can be controlled by the controller for the purpose of setting a flow of gas. The temperature sensor is a sensor capable of measuring the temperature of the object mount and of communicating this temperature to the controller by way of an appropriate signal. This can be desirable for providing feedback control of the cooling system. For example, a target temperature for the object mount might be settable in such an embodiment. Then, the controller is capable of increasing a flow of gas to such an extent that the temperature sensor detects the target temperature at the object mount, or detects the target temperature over a relatively long period of time, during which the object mount has reached a thermal equilibrium.

According to some embodiments, the reducing valve can be arranged at the supply port or in the flow of gas between the supply port and the first portion of the first connecting line cooled by the cooling mechanism, whereby a pressure of the gas in the whole cooling system is defined by a degree of opening of the reducing valve. For example, the pressure of the gas that is fed to the cooling system does not depend on a gas source used or on an amount of gas contained in the source in such a case, whereby the cooling system can be operated more reliably.

According to some embodiments, the first connecting line comprises an insulating layer that surrounds the first connecting line in a second portion between the cooling mechanism and the object mount and that reduces a heat transfer between the second portion of the first connecting line and the surroundings. For example, it can be desirable that the first portion of the first connecting line is free from an insulating layer surrounding the latter such that a heat transfer between the cooling mechanism and the gas can be performed efficiently. Moreover, the insulating layer is not present on the third and the fourth connecting line. For example, the insulating layer is a cladding of the connecting line in the second portion using a material which has a small coefficient of thermal conductivity. An insulating layer can also be realized by virtue of the connecting line being surrounded by a housing within which a vacuum is created. A vacuum also prevents the connecting line from icing over since the portion of the connecting lines surrounded by the insulating layer does not come into contact with suspended water from the surroundings.

It may also be desirable for the insulating layer to also surround the second connecting line and the heat exchanger so that unwanted heating of the gas in the second connecting line and in the heat exchanger is reduced. For example in the case of an insulating layer realized by way of a vacuum, the aforementioned vacuum housing can surround the first connecting line, the second connecting line and the heat exchanger. The insulating layer can also be realized by virtue of the aforementioned vacuum housing being connected to a vacuum chamber of the particle beam system.

According to some embodiments, the cooling mechanism comprises a cooling space. The cooling space is a volume into which a coolant, for example liquid nitrogen, can be filled. In this context, the coolant can be filled into the cooling space before a start of the cooling operation. For example, the first portion of the first connecting line is submersed in this liquid nitrogen during a cooling operation of the particle beam system. Moreover, performing a thawing operation after a certain duration of the cooling operation of the particle beam system can help remove deposits from the first connecting line that arise when contaminants of the gas deposit in the cooling system on account of the low temperature and increasingly block the first connecting line. To this end, the gas is fed in such a way during the thawing operation to the cooling system that uncooled gas flows through the first connecting line. Accordingly, it is desirable for the thawing operation if the cooling mechanism can be put out of operation so that the gas is not cooled in the first portion of the first connecting line either. To this end, the first portion of the first connecting line can be submersed in the liquid nitrogen prior to the cooling operation and also be non-destructively removed again from the latter prior to the thawing operation. As a result, the cooling mechanism can be put out of operation.

According to some embodiments, the particle beam system furthermore comprises a vacuum cladding which delimits a vacuum chamber. For example, the vacuum cladding is a metal housing of the particle beam system. A vacuum is created in the vacuum chamber during the operation of the particle beam system in order to reduce unwanted interactions of the particle beam with an atmosphere. In this context, it can be desirable for components whose operation does not require a vacuum to be arranged outside of the vacuum chamber since this can reduce an extent of the vacuum chamber and prevent a superfluous energy increase when creating the vacuum. For example, the cooling mechanism can be arranged outside of the vacuum chamber. Moreover, as described above, the insulating layer might be connected to the vacuum chamber such that a pump simultaneously creates the vacuum for scanning the object using the particle beam and the vacuum for insulating the second portion of the first connecting line and the further components.

According to some embodiments, the cooling system of the particle beam system further comprises a switchover valve for switching between the cooling operation and the thawing operation, wherein during thawing operation the first end of the third connecting line is connected to the inlet opening of the first passage through the heat exchanger, and the second end is connected to the outlet, and wherein during thawing operation the first end of the fourth connecting line is connected to the outlet opening of the second passage through the heat exchanger, and the second end is connected to the supply port. This means that during the cooling operation the gas is conducted through the cooling system in such a way that the gas initially flows through the first passage through the heat exchanger, whereby the gas is pre-cooled, subsequently cooled in the first portion of the first connecting line and then cools the object mount by virtue of the gas flowing through the coolant passage in the object mount. After leaving the coolant passage through the object mount, the gas flows through the second passage through the heat exchanger in order to pre-cool gas that is newly fed. On the other hand, during the thawing operation, the gas is conducted through the cooling system in such a way that the gas initially flows through the second passage through the heat exchanger and the coolant passage through the object mount, whereby the object mount is heated. Then the gas flows through the first portion of the first connecting line and removes deposits that have accumulated there during the preceding cooling operation, and the gas is subsequently released into the surroundings after flowing through the first passage through the heat exchanger.

It should be observed that the aforementioned labels of inlet port and output port of the coolant passage serve illustrative purposes and do not define any flow direction of the gas. For example, the operation used predominantly is that in which the switchover valve is operated in the first position. This operation is also referred to as cooling operation. Accordingly, the inlet port of the coolant passage is the port of the coolant passage through which the gas enters the coolant passage during cooling operation, and the outlet port of the coolant passage is the port through which the gas emerges from the coolant passage during the cooling operation. Particular attention should be drawn to the fact that the assignment of the inlet port and outlet port does not depend on the current operation of the switchover valve.

According to some embodiments, the switchover valve is a 5/2-port directional control valve. The 5/2-port directional control valve is a valve with five ports and two positions.

The five ports are divided into two inlet ports and three outlet ports, wherein one of the three outlet ports is connected to one of the inlet ports in both positions and the other two outlet ports are each connected to one of the inlet ports in only one of the positions. Alternatively, a 4/2-port directional control valve, for example, can be used. The 4/2-port directional control valve is a valve with four ports and two positions, wherein the four ports are divided into two input ports and two output ports, and in the second position the two output ports are connected to the respective other input port in comparison with the first position.

According to some embodiments, the particle beam system further comprises an object stage, which holds the object mount and for example is connected to an actuator which can be driven to displace the object mount-mounted object over the object stage relative to the lens for focusing the particle beam. For example, the object mount is held at a distance from the object stage by way of spacers in order to reduce the heat transfer between the object mount to be cooled and the object stage connected to the actuator. Fewer than ten and for example three spacers are used to maintain the distance between the object mount and the object stage. For example, the spacers are made of a material which has a low coefficient of thermal conductivity and are manufactured in spherical shape in order to minimize the heat transfer from the object stage to the object mount. Alternatively, the object mount might for example not be carried by an object stage but be guided into the vacuum chamber through a vacuum lock on a connection. In this case, the vacuum lock is a feedthrough through the vacuum cladding with two seals, which close with a time offset from one another when the object mount is removed from the vacuum chamber such that the vacuum prevalent within the vacuum chamber can be maintained during the removal.

According to some embodiments, a method for operating the particle beam system comprises an operation of the particle beam system in a first operating mode, specifically the cooling operation. During the cooling operation, the gas is initially fed to the supply port, wherein the gas is pre-cooled when flowing through the first passage through the heat exchanger. Thereupon, the gas in the second portion of the first connecting line is cooled using the cooling mechanism, and the object mount and an object arranged on the object mount are cooled by virtue of the cooled gas flowing through the coolant passage in the object mount. After the gas leaves the coolant passage in the object mount, the gas flows through the second passage through the heat exchanger in order to pre-cool, by way of heat exchange, gas that is newly fed. The cooled object is scanned using the particle beam, and signals created by the object upon the incidence of the particle beam are captured by the detector, whereby a particle-optical image can be created. A liquid nitrogen consumption can be reduced because a coldness induced in the gas can be used more effectively.

The gas that is fed is nitrogen according to some embodiments. In this case, it should be observed that gases usually contain contaminants. Herein, gases in which a proportion of the contaminants vis-à-vis a proportion of the actual nitrogen is low are referred to as nitrogen. For example, the nitrogen has less than 1 volume-% of contaminants.

According to some embodiments, the method comprises an operation of the particle beam system in a second operating mode, specifically the thawing operation. For the thawing operation, the switchover valve is initially used to switch over from the cooling operation to the thawing operation. Thereupon, gas is fed to the supply port, and the object mount is heated using the gas that is fed. For a renewed switchover into the cooling operation, this further comprises a switchover with the switchover valve.

### BRIEF DESCRIPTION OF THE DRAWINGS

Specific embodiments will be explained in detail below on the basis of the figures, in which:

FIG. 1 shows a particle beam system having a cooling system according to one embodiment; and

FIG. 2 shows a flowchart for explaining a method for operating a particle beam system shown in FIG. 1.

### DETAILED DESCRIPTION

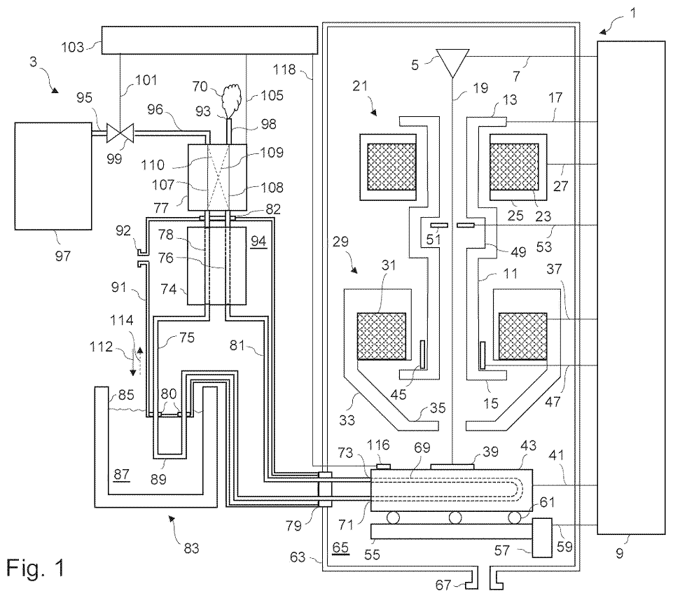

FIG. 1 shows a particle beam system 1 having a cooling system 3 according to one embodiment. The particle beam system 1 comprises a particle beam source 5 which is connected to a controller 9 via an electrical line 7. The controller 9 is capable of supplying a first electric potential to the particle beam source 5 via the electrical line 7. The particle beam system 1 further comprises a beam tube 11 having an upper end 13 and a lower end 15. The beam tube 11 is connected to the controller 9 via an electrical line 17. By way of the electrical line 17, the controller 9 is capable of supplying a second electric potential to the beam tube 11. During the operation of the particle beam system 1, the controller 9 supplies the first electric potential to the particle beam source 5, whereby particles are released from the particle beam source 5. Moreover, the controller 9 supplies the beam tube 11 with a second electric potential that differs from the first electric potential such that the particles released from the particle beam source 5 are accelerated towards the upper end 13 of the beam tube 11 and form a particle beam 19.

It should be observed that the upper end 13 of the beam tube 11 acts like an acceleration electrode in the example described herein. However, provision can be made for an additional acceleration electrode which may be comprised in the particle beam source 5, for example, in the particle beam system 1 shown in FIG. 1.

The particle beam 19 passes through a condenser lens 21 which comprises a pole shoe 25 and a coil 23. The coil 23 of the condenser lens 21 is connected to the controller 9 via an electrical line 27, with the result that this controller is capable of supplying an electric current to the coil 23 of the condenser lens 21, whereby the coil 23 of the condenser lens 21 creates a magnetic field. The magnetic field created by the coil 23 of the condenser lens 21 enters the beam tube 11 at an opening of the pole shoe 25 and influences the particle beam 19 passing through the condenser lens 21. The condenser lens 21 is used to collimate the particle beam 19. However, the condenser lens 21 can also be used to focus the particle beam 19. Even though the condenser lens 21 is depicted as a magnetic lens in FIG. 1, the condenser lens 21 might also be any other lens suitable for influencing the particle beam 19. For example, the condenser lens can be an electrostatic lens, such as a single lens.

The particle beam 19 furthermore passes through an objective lens 29 which comprises a coil 31 and a pole shoe 33 with a lower end 35. The coil 31 of the objective lens 29 is connected to the controller 9 via an electrical line 37, with the result that this controller is capable of supplying an electric current to the coil 31 of the objective lens 29, whereby the coil 31 of the objective lens 29 creates a magnetic field. The pole shoe 33 of the objective lens 29 has a lower end 35, which is arranged below the lower end 15 of the beam tube 11. The pole shoe 35 of the objective lens 29 is open towards the particle beam 19, with the result that the magnetic field created by the coil 31 of the objective lens 29 is able to enter the pathway of the particle beam 19 in order to influence the letter.

The particle beam 19 is focused on an object 39 by the objective lens 29. It should be observed that focusing of the particle beam 19 can also be performed by the condenser lens 21. Moreover, in a manner similar to the condenser lens 21, the objective lens 29 can also be an electrostatic lens, for example a single lens, rather than the magnetic lens shown in FIG. 1.

The particle beam 19 also passes through an electrostatic lens which is formed by the lower end 15 of the beam tube 11 and the object 39. Via an electrical line 41 and an object mount 43, a third potential can be supplied to the object 39 by the controller 9. In the particle beam system 1 described herein, it is desirable for the third electric potential to be supplied to the object 39 corresponds to a zero potential in order to avoid an energy supply by the controller 9.

An electric field between the lower end 15 of the beam tube 11 and the object 39 is defined by a difference between the second electric potential supplied to the beam tube 11 and the third electric potential supplied to the object 39. The particle beam 19 is influenced when passing through this electric field prevalent between the lower end 15 of the beam tube 11 and the object 39. This electric field creates an effect of a focusing lens.

This structure can also be referred to as a combination of lens since there is a significant overlap between the electric field of the electrostatic lens and the magnetic field of the objective lens 29.

An incidence location of the particle beam 19 on the object 39 is influenced by a deflection arrangement 45. In the example shown in FIG. 1, the deflection arrangement 45 comprises a plurality of pairs of electrodes which create an electric field that deflects the particle beam 19 when passing through the electric field when, via an electrical line 47, a voltage is supplied between the electrodes of a pair by the controller 9.

When the particle beam 19 is incident on the object 39, the object 39 emits electrons which are accelerated into the beam tube 11 on account of the focusing electrostatic lens between the object 39 and the lower end 15 of the beam tube 11. The beam tube 11 also comprises a space 49 for components, in which, as shown in FIG. 1, a detector 51, for example, is arranged, the latter being connected to the controller 9 via an electrical line 53. The detector 51 comprises a detector area for detecting the electrons entering into the beam tube 11. The detector 51 creates a detector signal which represents a number of electrons incident on the detector 51 and transmits the detector signal to the controller 9 via the electrical line 53.

The particle beam system 1 creates an image of the object 39 by virtue of the controller 9 setting different voltage values at the deflection arrangement 45 and assigning each of these voltage values to a detector signal. To this end, the detector signals and the voltage values can be stored in a memory of the controller 9.

The particle beam system 1 further comprises an object stage 55. The object stage 55 can be moved by an actuator 57, wherein the actuator 57 can be activated by the controller 9 via an electrical line 59. For example, a distance between the lower end 35 of the pole shoe 33 of the object lens 29 and the object 39, which can also be referred to as the working distance, can be changed by way of the actuator 57.

The object stage 55 carries the object mount 43 at a distance which is defined by spacers 61 between the object stage 55 and the object mount 43. As shown in FIG. 1, the spacers 61 might have a spherical form in order to keep a contact area between the object mount 43 and the spacers 61, or between the object stage 55 and the spacers 61, as small as possible. Reducing this contact area reduces the heat transfer between the object stage 55 and the object mount 43 to be cooled.

The particle beam system 1 further comprises a vacuum cladding 63 which surrounds a vacuum chamber 65 in which the above-described components of the particle beam system 1, with the exception of the controller 9, are arranged. Air is sucked out of the vacuum chamber 65 using a pump (not shown) connected to a pump nozzle 67, and hence a vacuum is created.

The particle beam system 1 further comprises the cooling system 3. The cooling system 3 comprises a coolant passage 69 in the object mount 43. The object mount 43 can dissipate heat to a coolant by way of the coolant passage 69. The coolant used to this end is a gas 70, for example nitrogen. For the above-described purpose, the coolant passage 69 comprises an inlet port 71, in which the nitrogen 70 flows into the coolant passage 69 during cooling operation, and an outlet port 73, from which the nitrogen 70 flows out of the coolant passage 69 during the cooling operation.

The inlet port 71 of the coolant passage 69 is connected to a heat exchanger 74 via a first connecting line 75. To this end, a first end of the connecting line 75 is connected to the input port 71 of the coolant passage 69, the connecting line 75 is guided out of the vacuum chamber 65 through a vacuum seal 79 through the vacuum cladding 63 and a second end of the connecting line 75 is connected to a first passage 78 through the heat exchanger 74. The vacuum seal 79 is a seal which hermetically closes off an opening in the vacuum cladding 63. For example, the vacuum seal 79 is a rubber seal or a metal seal. For example, the vacuum seal 79 shown in FIG. 1 is a double feedthrough which in addition to the first connecting line 75 also guides a second connecting line 81 out of the vacuum chamber 65 through the vacuum cladding 63. The second connecting line 81 is connected at a first end to the outlet port 73 of the coolant passage 69 and connected at a second end to a second passage 76 through the heat exchanger 74.

The cooling system 3 moreover comprises a further vacuum cladding 91 which surrounds a portion of the first connecting line 75, the second connecting line 81 and the heat exchanger 74. The vacuum cladding 91 comprises a pump nozzle 92, connected to which is a further pump (not shown) which when the pump is operated pumps air out of a vacuum chamber 94 surrounded by the vacuum cladding 91, whereby a vacuum is created in the vacuum chamber 94. The vacuum chamber 94 acts as a thermally insulating layer for a portion of the first connecting line 75, the second connecting line 81 and the heat exchanger 74. For example, the vacuum prevalent in the vacuum chamber 94 reduces a heat transfer between the components of the cooling system 3 surrounded by the vacuum cladding 91 and the surroundings. Moreover, the vacuum prevalent in the vacuum chamber 94 prevents an icing over of water suspended in the surroundings at the first connecting line 75, the second connecting line 81 and the heat exchanger 74. It should be observed that the vacuum chamber 94 might be connected to the vacuum chamber 65 such that the vacuum in the vacuum chamber 94 can be created by the pump (not shown) at the pump nozzle 67. The pump nozzle 92 is not required in this case.

The cooling system 3 also comprises a cooling mechanism 83 which has a cooling space 85. Liquid nitrogen 87 is filled into the cooling space 85, for example before the cooling system is put into operation, and a first portion 89 of the first connecting line 75 is submersed in the liquid nitrogen 87. To this end, the first portion 89 of the first connecting line 75 is led out of the vacuum chamber 94 via vacuum seals 80 through the vacuum cladding 91. The nitrogen 70 flowing through the first portion 89 of the first connecting line 75 is cooled in the cooling mechanism 83 by the liquid nitrogen 87.

The heat exchanger 74 comprises the first passage 76 and the second passage 78 and is a countercurrent heat exchanger, in which the nitrogen 70 flows in opposite directions through the first passage 78 and the second passage 76. By way of a vacuum seal 82, the first passage 78 and the second passage 76 through the heat exchanger 74 are each connected to a switchover valve 77. The heat exchanger 74 enables an efficient heat transfer between the nitrogen 70 in the first passage 78 through the heat exchanger 74 and the nitrogen 70 in the second passage through the heat exchanger 74. Even though the heat exchanger 74 in FIG. 1 is depicted as a simple countercurrent heat exchanger, use can be made of any heat exchanger that is suitable for the present purposes. For example, use can be made of a heat exchanger in which the first passage 78 and the second passage 78 are in the form of two concentric tubes such that the second passage 76 surrounds the first passage 78. What the heat exchanger 74 achieves is that the nitrogen 70 in the first passage 78 through the heat exchanger 74 is pre-cooled by the nitrogen 70 in the second passage 76 through the heat exchanger 74 before the nitrogen 70 is cooled in the first portion 89 of the first connecting line 75. The upshot of the pre-cooling of the nitrogen 70 in the first passage 78 through the heat exchanger 74 is that a consumption of the liquid nitrogen 87 in the cooling mechanism 83 is reduced since the liquid nitrogen 87 absorbs less heat from the nitrogen 70, and hence evaporates in a smaller quantity. Moreover, for example in a case in which the object mount 43 has reached a target temperature and is only be kept at this target temperature, this prevents the nitrogen 70 from being cooled and released in cooled fashion into the surroundings. This also reduces an energy consumption of the cooling system 3.

The cooling system 3 also comprises an outlet 93, from which the nitrogen 70 is released. The outlet 93 is connected to the switchover valve 77 via a fourth connecting line 98. Moreover, the cooling system 3 comprises a supply port 95 for feeding the nitrogen 70 into the cooling system 3. To this end, the supply port 95 is connected to a nitrogen reservoir 97, for example a nitrogen flask or a nitrogen tank. Moreover, the supply port 95 is connected to the switchover valve 77 via a third connecting line 96. To be able to set an inflow of nitrogen 70 from the nitrogen reservoir 97, the supply port 95 is connected to the switchover valve 77 via a reducing valve 99. For example, the reducing valve 99 is a magnetic valve, which can be controlled electrically. For control purposes, the reducing valve 99 is connected to a controller 103 via an electrical line 101. For example, the controller 103 determines a current that should be supplied to a magnetic valve in order to attain a target flow of the nitrogen 70 and feeds the determined current to the reducing valve 99.

The switchover valve 77 is connected for control purposes to the controller 103 via an electrical line 105. The switchover valve 77 shown in FIG. 1 is a 4/2-port directional control valve; however, the switchover valve 77 can also be of a different type, for example a 5/2-port directional control valve. For a simplified illustration, the 4/2-port directional control valve as shown in FIG. 1 is described below.

The switchover valve 77 comprises four ports, which are connected to the third connecting line 96, the fourth connecting line 98, the first passage 78 through the heat exchanger 74 and the second passage 76 through the heat exchanger. The switchover valve 77 further has a first position and a second position. The first position is represented by the solid paths 107 and 108, and the second position is represented by the dashed paths 109 and 110. Should the switchover valve 77 be in the first position represented by the solid paths 107 and 108, the supply port 95 is connected to the first passage 78 through the heat exchanger 74, and the outlet 93 is connected to the second passage 76 through the heat exchanger 74. Accordingly, in the first position of the switchover valve 77, the nitrogen 70 flows out of the nitrogen reservoir 97 into the first passage 78 through the heat exchanger 74 and subsequently into the first connecting line 75. The nitrogen 70 is cooled in the first portion 89 of the first connecting line 75 and flows through the coolant passage 69 in the object mount 43, whereby the object mount 43 and the object 39 arranged on the object mount 43 are cooled. Subsequently, the nitrogen 70 flows through the second connecting line 81 into the second passage 76 through the heat exchanger 74 and performs a heat exchange with the nitrogen 70 in the first passage 78 through the heat exchanger 74. Thereupon, the nitrogen 70 flows out of the second passage 76 through the heat exchanger 74 to the outlet 93 and is released into the surroundings there. The flow of the nitrogen 70 in the first position of the switchover valve 77 is represented by the solid arrow 112 in FIG. 1.

The switchover valve 77 serves to enable a switchover between a cooling operation and a thawing operation of the particle beam system 1. Deposits in the first portion 89 of the first connecting line 75 are removed during the thawing operation; for example, the deposits arise by virtue of contaminants contained in the nitrogen 70 freezing in the first portion 89 of the first connecting line 75.

In order to remove the deposits using the thawing operation, the controller 103 is able to change the position of the switchover valve 77 by way of an electrical line 105, and hence put the switchover valve 77 into the second position. Additionally, the cooling mechanism 83 are taken away by virtue of the first portion 89 of the first connecting line 75 being taken out of the liquid nitrogen 87. It should be observed that removal of the cooling mechanism 83 is not mandatory. In a case in which the cooling mechanism 83 is a Peltier cooling mechanism for example, it is sufficient for the cooling mechanism 83 to have a lesser cooling power such that the nitrogen 70 is only cooled slightly during the operation of the switching valve 77 in the second position.

In the second position of the switchover valve 77 represented by the dashed paths 109 and 110, the supply port 95 is connected to the second connecting line 81, and the outlet 93 is connected to the first connecting line 75. Accordingly, the nitrogen 70 flows from the nitrogen reservoir 97 into the second connecting line 81 in the second position of the switchover valve 77. Thereupon, the uncooled nitrogen 70 flows through the coolant passage 69 in the object mount 43 and warms the latter. Thereupon, the nitrogen 70 flows through the first connecting line 75 and heats the first portion 89 of the first connecting line 75, whereby the deposits are dissolved. The dissolved deposits are then released to the surroundings by the nitrogen 70 flowing through the first connecting line 75 and the outlet 93. The flow of the nitrogen 70 in the second position of the switchover valve 77 is represented by the dashed arrow 114 in FIG. 1. The dissolved deposits cannot be deposited in the cooling system 3 again as a result of the reversal of the flow direction of the nitrogen 70 in the first connecting line 75 and the second connecting line 81 in the second position of the switchover valve 77 since the object mount 43 or the first connecting line 75 is heated using the nitrogen 70 which does not yet contain any dissolved deposits.

The cooling system 3 further comprises a temperature sensor 116 which is attached to the object mount 43 in order to detect a temperature of the object mount 43. For example, the temperature sensor 116 is a resistance temperature sensor. The temperature sensor 116 creates a signal which represents the temperature of the object mount 43 and transmits the signal to the controller 103 via an electrical line 118. For example, the temperature sensor 116 serves to determine whether there should be a switchover into the second position of the switchover valve 77 or into the first position of the switchover valve 77, as will be described in detail below.

The above-described particle beam system 1 is capable of reducing consumption of liquid nitrogen and achieving the aforementioned objective. It should be observed that the controller 103 of the cooling system 3 need not necessarily be separate from the controller 9 as shown in FIG. 1. Moreover, a plurality of components of the cooling system 3 depicted outside of the vacuum chamber 65 in FIG. 1 might also be arranged within the vacuum chamber 65.

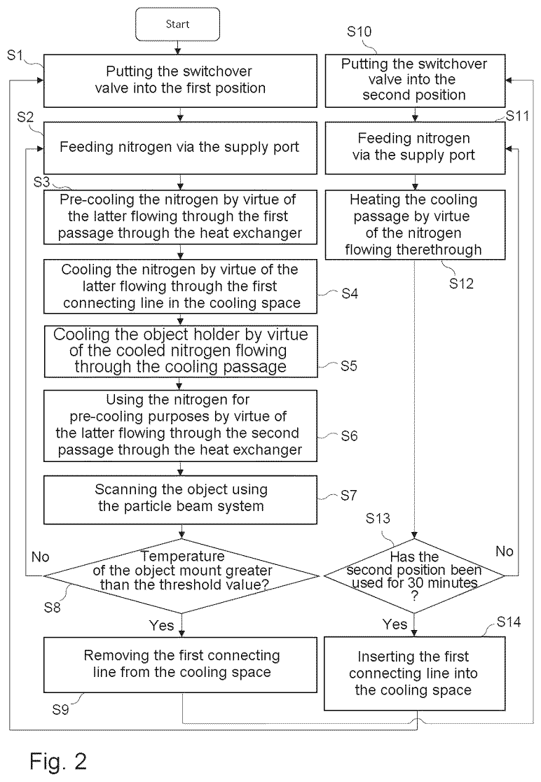

FIG. 2 shows a flowchart for explaining a method for operating the particle beam system 1 shown in FIG. 1. In this case, the method comprises an operation of the particle beam system 1 in a first operating mode, which comprises steps S1 to S8, an operation of the particle beam system 1 in a second operating mode, which comprises steps S10 to S13, and steps S9 and S14 for switching over between the first operating mode and the second operating mode.

In step S1, the controller 103 puts the switchover valve 77 into the first position, which is depicted by the solid paths 107 and 108 in FIG. 1. Thereupon, the controller 103 sets the flow of the nitrogen 70 at the reducing valve 99 in step S2, the flow then flowing from the nitrogen reservoir 97 to the first connecting line 75 through the switchover valve 77.

After flowing through the switchover valve 77 in the first position, the nitrogen 70 flows through the first passage 78 through the heat exchanger 74 and is pre-cooled there in step S3 by heat exchange with the nitrogen 70 in the second passage 76 through the heat exchanger 74.

The nitrogen 70 pre-cooled in step S3 is then cooled by the cooling mechanism 83 in step S4 when flowing through the first portion 89 of the first connecting line 75. In the case of the particle beam system 1, the nitrogen 70 is cooled by the liquid nitrogen 87 for example when flowing through the first portion 89 of the first connecting line 75. In step S5, the nitrogen 70 then flows through the coolant passage 69 in the object mount 43 and cools the object mount 43 and the object 39 situated thereon.

In step S6, after leaving the coolant passage 69 in the object mount 43, the nitrogen 70 flows through the second passage 76 through the heat exchanger 74 and is used in the second passage 76 through the heat exchanger 74 to pre-cool the nitrogen 70 flowing through the first passage 78 through the heat exchanger 74, by virtue of performing heat exchange between the nitrogen 70 in the second passage 76 through the heat exchanger 74 and the nitrogen 70 in the first passage 78 through the heat exchanger 74. After flowing through the second passage 76 through the heat exchanger 74, the nitrogen 70 flows through the switchover valve 77 and is released to the surroundings. The upshot of the pre-cooling of the nitrogen 70 in the first passage 78 through the heat exchanger 74 is that a consumption of the liquid nitrogen 87 in the cooling mechanism 83 and an energy consumption of the cooling system 3 are reduced since the liquid nitrogen 87 absorbs less heat from the nitrogen 70, and hence evaporates in a smaller quantity.

The cooled object 39 can then serve to record a particle-microscopic image using the particle beam system 1. For example, the controller 9 scans a region on the object 39 in step S7 by virtue of the controller 9 applying a plurality of successive voltages to the electrodes of the deflection arrangement 45 and assigning the voltages to the respective captured detector signal.

During the operation of the particle beam system 1 in the first operating mode, the controller 103 monitors a temperature of the object mount 43 using the temperature sensor 116. Should the first portion 89 of the first connecting line 75 have a large amount of deposits, the cooling power of the cooling system 3 is limited, and the object mount 43 cannot be cooled sufficiently. The temperature of the object mount 43 increases accordingly, and this is detected by the temperature sensor 116. For this reason, the controller 103 evaluates the signal of the temperature sensor 116 in step S8 and compares the signal with a predetermined threshold value. For example, such a threshold value is 5° C. greater than a target temperature of the object mount 43. If the threshold value is not exceeded by the measured temperature of the object mount 43, then the first operating mode is still carried out going forward. More precisely, nitrogen 70 continues to be fed, the nitrogen 70 is pre-cooled and cooled, the object mount 43 is cooled using the nitrogen 70 and the object 39 is scanned using the particle beam system 1, as described in steps S2 to S7 in FIG. 2.

If the threshold value is exceeded by the measured temperature of the object mount 43, then there is a switchover to the second operating mode. To this end, the first portion 89 of the first connecting line 75 is initially removed from the liquid nitrogen 87 in step S9. For example, this can be implemented by a user of the particle beam system 1 after they were informed via a user interface that a removal of the first portion 89 of the first connecting line 75 from the liquid nitrogen 87 is used. After the user removed the first portion 89 of the first connecting line 75 from the liquid nitrogen 87, they can for example acknowledge the notification via the user interface so that the method can be continued by the particle beam system 1. Alternatively, the first portion 89 of the connecting line 75 can be secured to a guide which can be moved out of the cooling mechanism 83 by way of an actuator. Such an actuator can be controlled by the controller 103.

After the first portion 89 of the first connecting line 75 has been removed from the cooling mechanism 83, the controller 103 continues with step S10, in which the controller 103 puts the switchover valve 77 into the second position, which is represented in FIG. 1 by the dashed paths 109 and 110. Thereupon, the controller 103 sets the flow of nitrogen 70 on the reducing valve 99 in step S11, in such a way that the nitrogen 70 is fed via the supply port 95.

Since the direction of flow of the nitrogen 70 has been reversed in relation to the first position of the switchover valve 77 as a result of the second position of the switchover valve 77, as depicted by the solid arrow 112 and for example the dashed arrow 114 in FIG. 1, the uncooled nitrogen 70 flows through the coolant passage 69 in the object mount 43, as described in step S12 in FIG. 2. The coolant passage 69 and the object holder 43 are heated as a result. The uncooled nitrogen 70 also heats the first portion 89 of the first connecting line 75 and removes deposits present in the first portion 89 of the first connecting line 75.

The controller 103 monitors the duration of the operation of the particle beam system 1 in the second operating mode. For example, the controller 103 carries out a check in step S13 as to whether a predetermined operating duration has elapsed since the start of the operation of the particle beam system 1 in the second operating mode. For example, the predetermined operating duration is half an hour. If the predetermined operating duration since the start of the operation of the particle beam system 1 in the second operating mode has not elapsed, then the controller 103 carries out the operation of the particle beam system 1 in the second operating mode. More precisely, the feed of the nitrogen 70 and the heating of the coolant passage 69 through the object mount 43 in steps S11 and S12 are repeated, as is the check regarding the duration of the operation of the particle beam system 1 in the second operating mode in step S13.

If the controller 103 in step S13 determines that the predetermined operating duration since the start of the operation of the particle beam system 1 in the second operating mode has elapsed, then there is a switchover to the first operating mode. To this end, the first portion 89 of the first connecting line 75 is submersed in the liquid nitrogen 87 in step S14, and the controller 103 continues with step S1. In a manner similar to what was described in relation to step S9, the first portion 89 of the first connecting line 75 can be submersed in the liquid nitrogen 87 by a user after they were notified that the insertion of the first portion 89 of the first connecting line 75 into the cooling mechanism 83 is desired, or a guide by which step S14 can be performed by the controller 103 might be present. It should be observed that the above-described predetermined operating duration of half an hour serves illustrative purposes, and any other value can be chosen for the operating duration. Moreover, it should also be observed that the temperature of the object mount 43 can also be monitored using the temperature sensor 116 in step S13, similar to what occurred in step S8. In such a case, the controller 103 can for example compare the temperature value measured by the temperature sensor 116 with a room temperature, a temperature of the nitrogen 70 when leaving the nitrogen reservoir 97, or the like.

It should be observed that the cooling system 3 might comprise further sensors that create signals that can be used by the controller 103 in step S8 and/or in step S13. For example, a further temperature sensor can be arranged on the first portion 89 of the first connecting line 75 and can be connected to the controller 103 via an electrical line. In that case, the controller 103 can compare a temperature measured by this temperature sensor on the first portion 89 of the first connecting line 75 with a predetermined threshold value in step S8 and/or in step S13. For example, the predetermined threshold value is a value slightly above the usual temperature of liquid nitrogen, and can be −190° C. If the temperature measured on the first portion 89 of the first connecting line 75 exceeds the threshold value in step S8, then the process continues with step S9 as described above. Otherwise, the process continues with steps S2 to S7, as described above.

Moreover, the controller 103 can compare the temperature measured on the first portion 89 of the first connecting line 75 with a second threshold value which is higher than the aforementioned threshold value and for example represents a room temperature. As a result, the controller 103 can determine whether step S9 is desired. For example, the controller 103 need not notify the user of the particle beam system 1 with regards to the desire to remove the first portion 89 of the first connecting line 75 from the liquid nitrogen 87 and instead skip step S9 if the temperature measured at the first portion 89 of the first connecting line 75 is greater than the second threshold value, i.e. greater than the room temperature for example.

If the temperature measured on the first portion 89 of the first connecting line 75 drops below the threshold value in step S13, then the process continues with step S14, as described above. Otherwise, the process continues with steps S11 and S12, as described above. Using such a control of the cooling system 3, it is possible to automatically switch from the cooling operation of the cooling system 3 to the thawing operation if the first portion 89 of the first coolant line 75 is removed from the liquid nitrogen 87 or the liquid nitrogen 87 has been consumed.

A plurality of further embodiments are conceivable. For example, the controller 103 and the controller 9 could be implemented in a common controller, for example an all-purpose computer. Moreover, the coolant is not restricted to nitrogen. The embodiment of the particle beam system 1 described can be implemented with any coolant in which contaminations in the coolant deposit on account of the coolant being cooled.

What is claimed is:

1. A particle beam system, comprising:
an object mount configured to mount an object;
a particle beam source configured to create a particle beam;
a lens configured to focus the particle beam on the object;
a detector configured to detect signals created via the interaction of the particle beam and the object; and
a cooling system configured to cool the object mount, the cooling system comprising:
a coolant passage through the object mount, the coolant passage comprising an inlet port and an outlet port;
a supply port configured to feed a gas;
an outlet configured to remove the gas;
a heat exchanger comprising first and second passages, the first passage comprising an inlet opening and an outlet opening, the second passage comprising an inlet opening and an outlet opening;
a first connecting line, the first connecting line comprising a end connected to the inlet port of the coolant passage through the object mount, and the first connecting line comprising a second end connected to the outlet opening of the first passage through the heat exchanger;
a second connecting line, the second connecting line comprising a first end connected to the outlet port of the coolant passage through the object mount, and the second connecting line comprising a second end connected to the inlet opening of the second passage through the heat exchanger;
a third connecting line comprising first and second ends, the third connecting line configured so that during a cooling operation: the first end of the third connecting line is connected to the inlet opening of the first passage through the heat exchanger; and the second end of the third coolant line is connected to the supply port;
a fourth connecting line comprising first and second ends, the fourth connecting line configured so that during the cooling operation: the first end of the fourth connecting line is connected to the outlet opening of the second passage through the heat exchanger; and the second end of the fourth connecting line is connected to the outlet; and
a cooling mechanism configured to cool at least a first portion of the first connecting line.

2. The particle beam system of claim 1, wherein the cooling system further comprises:
a reducing valve along a flow of gas between the supply port and the outlet, the reducing valve configured to variably resist the flow of gas through the reducing valve;
a temperature sensor configured to output representing a temperature of the object mount; and
a controller configured to control the reducing valve based on the signal representing the temperature of the object mount.

3. The particle beam system of claim 2, wherein the reducing valve is along the flow of gas between the supply port and the cooling mechanism.

4. The particle beam system of claim 1, wherein the first connecting line comprises an insulating layer surrounding the first connecting line in a second portion between the cooling mechanism and the object mount.

5. The particle beam system of claim 4, wherein the insulating layer also surrounds the second connecting line and the heat exchanger.

6. The particle beam system of claim 1, wherein the cooling mechanism comprises a cooling space through which a first portion of the first connecting line passes.

7. The particle beam system of claim 6, wherein the first portion of the connecting line is free from an insulating layer surrounding it.

8. The particle beam system of claim 6, wherein the cooling space is configured to accommodate liquid nitrogen.

9. The particle beam system of claim 6, wherein the first portion of the connecting line is non-destructively removable from the cooling space and subsequently re-insertable therein.

10. The particle beam system of claim 1, further comprising a vacuum cladding delimiting a vacuum chamber, wherein the object mount is within the vacuum chamber, and the cooling mechanism is outside of the vacuum chamber.

11. The particle beam system of claim 1, wherein:
the cooling system further comprises a switchover valve configured to switch between the cooling operation and a thawing operation;
during a thawing operation:
the first end of the third connecting line is connected to the inlet opening of the first passage through the heat exchanger;
the second end of the third connecting line is connected to the outlet;
the first end of the fourth connecting line is connected to the outlet opening of the second passage through the heat exchanger; and
the second end of the fourth connecting line is connected to the supply port.

12. The particle beam system of claim 11, wherein the switchover valve comprises a 5/2-port directional control valve.

13. The particle beam system of claim 1, further comprising an object stage that is displaceable relative to the lens, wherein the object stage carries the object mount.

14. The particle beam system of claim 13, wherein the object mount is thermally insulated from the object stage.

15. The particle beam system of claim 1, wherein:
the object mount comprises a main face facing the object stage;
the object stage comprises a main face facing the object mount; and
the particle beam system comprises less than 10 spacers between the object mount and the object stage to maintain a distance between the main face of the object mount and the main face of the object stage.

16. A method, comprising:
providing the particle beam system of claim 1;
operating the particle beam system in a first operating mode comprising:
feeding gas to the supply port;
pre-cooling the gas in the first passage using the heat exchanger;
cooling the gas in the second portion of the first connecting line using the cooling mechanism;
using the cooled gas to cool the object mount and an object arranged on the object mount;
using the gas in the second passage through the heat exchanger for pre-cooling with the heat exchanger after the object mount has been cooled; and
scanning the particle beam over the object and detecting signals using the detector.

17. The method of claim 16, wherein the gas comprises nitrogen gas.

18. The method of claim 16, further comprising operating the particle beam system in a second operating mode comprising:
switching the operation using the switchover valve;
feeding gas to the supply port; and
heating the object mount using the gas that is fed,
wherein the first operating mode further comprises a switchover of the operation using the switchover valve.

19. The method of claim 16, wherein the cooling mechanism is not operated in the second operating mode.

20. The method of claim 16, wherein:
the cooling mechanism comprises a cooling space through which a first portion of the first connecting line passes; and
the method further comprises, after operating the particle beam system in the first operating mode and before operating the particle beam system in the second operating mode, removing the first portion of the first connecting line from the cooling space.

21. The method of claim 16, wherein:
the cooling mechanism comprises a cooling space through which a first portion of the first connecting line passes; and
the method further comprises, before operating the particle beam system in the first operating mode, filling the cooling space with liquid nitrogen.

22. The method of claim 21, further comprising:
after operating the particle beam system in the first operating mode and before operating the particle beam system in the second operating mode, taking the first portion of the first connecting line from the cooling space; and
after operating the particle beam system in the second operating mode and before operating the particle beam system in the first operating mode, inserting the first portion of the first connecting line into the cooling space.

23. One or more machine-readable hardware storage devices comprising instructions that are executable by one or more processing devices to perform operations comprising the method of claim 16.

24. A system comprising:
one or more processing devices; and
one or more machine-readable hardware storage devices comprising instructions that are executable by the one or more processing devices to perform operations comprising the method of claim 16.
